(19) United States
(12) Patent Application Publication
(10) Pub. No.: US 2016/0035818 A1
(43) Pub. Date: Feb. 4, 2016

(54) FORMING A VERTICAL CAPACITOR AND RESULTING DEVICE

(71) Applicant: GLOBALFOUNDRIES Inc., Grand Cayman (KY)

(72) Inventors: Jan HOENTSCHEL, Dresden (DE); Stefan FLACHOWSKY, Dresden (DE); Gerd ZSCHÄTZSCH, Dresden (DE)

(21) Appl. No.: 14/447,167

(22) Filed: Jul. 30, 2014

(51) Int. Cl. H01L 49/02; H01L 27/02; H01L 29/78; H01L 27/06

(52) U.S. Cl. CPC H01L 28/92; H01L 28/91; H01L 27/0629; H01L 27/0207; H01L 29/785

(57) ABSTRACT

Methods for forming a vertical capacitance structure and the resulting devices are disclosed. Embodiments may include forming fins on a substrate; conformally forming a first metal layer over the fins; conformally forming an insulation layer over the first metal layer; and forming a second metal layer over the insulation layer.

### TECHNICAL FIELD

The present disclosure relates to a capacitance structure. The present disclosure is particularly applicable to a capacitance structure that requires less horizontal die area and is particularly applicable to 20 nanometer (nm) technology nodes and beyond.

### BACKGROUND

Continued scaling towards 14 nm very large scale integration (VLSI) complementary metal oxide semiconductor (CMOS) technologies increases the efforts and complexities to find manufacturable solutions because new materials, like high-k metal gate (HKMG) and ultralow-k dielectrics, need to be implemented for overcoming the physical restrictions at such small dimensions. Such scaling also provides an opportunity to create new approaches to simplify a given design, which makes it more flexible to offer additional and/or new devices. One major physical restriction is the loss of gate control at smaller dimensions, which cannot be compensated for within a planar environment. Vertical or three-dimensional (3D) device concepts, such as fin field-effect transistors (FinFETs) are needed to accomplish further scaling.

Multiple solutions currently exist for implementing capacitance for gate first HKMG technologies. A standard approach for implementing capacitance is a large planar capacitance structure. Such a structure, however, requires a large die area, particularly depending on the performance requirements of the capacitance. For gate last technologies, capacitance can be implemented by the same approach of a planar capacitance structure, in addition to large metal-insulator-metal (MIM) capacitance structures in upper metal layers. However, planar capacitance structures require too large an area for replacement gate/FinFET technologies.

A need, therefore, exists for a method of implementing capacitance for smaller areas without additional process complexity, and the resulting devices.

### SUMMARY

An aspect of the present disclosure is a method of forming a vertical capacitance structure.

Another aspect of the present disclosure is a vertical capacitance structure.

Additional aspects and other features of the present disclosure will be set forth in the description which follows and in part will be apparent to those having ordinary skill in the art upon examination of the following or may be learned from the practice of the present disclosure. The advantages of the present disclosure may be realized and obtained as particularly pointed out in the appended claims.

According to the present disclosure, some technical effects may be achieved in part by a method including forming fins on a substrate; conformally forming a first metal layer over the fins; conformally forming an insulation layer over the first metal layer; and forming a second metal layer over the insulation layer.

An aspect of the present disclosure includes forming a first contact connected to the first metal layer, with the first contact being isolated from the second metal layer. A further aspect includes forming a second contact connected to the second metal layer, with the second contact being isolated from the first metal layer. Another aspect includes conformally forming the second metal layer over the insulation layer. Yet another aspect includes forming a resist layer over the second metal layer. An additional aspect pertaining to conformally forming the insulation layer includes blanket depositing insulation material over the first metal layer; forming a patterned hardmask over the insulation material, where portions of the insulation material exposed by the patterned hardmask are aligned with trenches in the substrate between the fins; etching the insulation material according to the patterned hardmask; and removing the patterned hardmask and a top portion of the insulation material. Yet another aspect includes forming the first metal layer to a thickness of 20 to 60 nm; and forming the second metal layer to a thickness of 20 to 60 nm. Still another aspect includes forming the fins to a height of 80 to 200 nm and a pitch of 180 to 400 nm. An additional aspect includes forming 50 to 2000 fins.

Another aspect of the present disclosure is a device including: a substrate; fins formed on the substrate; a conformal first metal layer over the fins; a conformal insulation layer over the first metal layer; and a second metal layer over the insulation layer.

Aspects include a first contact connected to the first metal layer, with the first contact being isolated from the second metal layer. Another aspect includes a second contact connected to the second metal layer, with the second contact being isolated from the first metal layer. A further aspect includes the second metal layer being conformal. Another aspect includes a resist layer over the second metal layer. Still another aspect includes the first metal layer being formed to a thickness of 20 to 60 nm, and the second metal layer being formed to a thickness of 20 to 60 nm. A further aspect includes the fins being formed to a height of 80 to 200 nm and a pitch of 180 to 400 nm. An additional aspect is the device including 50 to 2000 fins.

Another aspect of the present disclosure is a method including defining a fin area and a device area on a substrate, the fin area including 50 to 2000 fins; conformally forming a first metal layer over the fin area to a thickness of 20 to 60 nm; conformally forming an insulation layer over the first metal layer; forming a second metal layer over the insulation layer to a thickness of 20 to 60 nm; and forming a resist layer over the second metal layer.

Aspects include forming a first contact to the first metal layer; and forming a second contact to the second metal layer, with the first contact being isolated from the second metal layer, and the second contact being isolated from the first metal layer. An additional aspect includes forming a FinFET device on the device area.

Additional aspects and technical effects of the present disclosure will become readily apparent to those skilled in the art from the following detailed description wherein embodiments of the present disclosure are described simply by way of illustration of the best mode contemplated to carry out the present disclosure. As will be realized, the present disclosure is capable of other and different embodiments, and its several details are capable of modifications in various obvious respects, all without departing from the present disclosure. Accordingly, the drawings and description are to be regarded as illustrative in nature, and not as restrictive.

### BRIEF DESCRIPTION OF THE DRAWINGS

The present disclosure is illustrated by way of example, and not by way of limitation, in the figures of the accompanying drawings and in which like reference numerals refer to similar elements and in which:

FIGS. 1 through 16 schematically illustrate a method for forming a vertical capacitance structure, in accordance with an exemplary embodiment; and

FIG. 17 schematically illustrates a vertical capacitance structure adjacent a FinFET, in accordance with an exemplary embodiment.

### DETAILED DESCRIPTION

In the following description, for the purposes of explanation, numerous specific details are set forth in order to provide a thorough understanding of exemplary embodiments. It should be apparent, however, that exemplary embodiments may be practiced without these specific details or with an equivalent arrangement. In other instances, well-known structures and devices are shown in block diagram form in order to avoid unnecessarily obscuring exemplary embodiments. In addition, unless otherwise indicated, all numbers expressing quantities, ratios, and numerical properties of ingredients, reaction conditions, and so forth used in the specification and claims are to be understood as being modified in all instances by the term “about.”

The present disclosure addresses and solves the current problem of the requirement for a large amount of horizontal die area attendant upon employing planar capacitance structures. In accordance with embodiments of the present disclosure, a vertical capacitance structure is formed that reduces the requirement for large horizontal die areas.

Methodology in accordance with an embodiment of the present disclosure includes forming fins on a substrate. Next, a first metal layer and an insulation layer are conformally formed over the fins, with the metal layer below the insulation layer. A second metal layer is formed over the insulation layer. The second metal layer can be conformal or not conformal. The second metal layer completes the vertical capacitance structure formed over the fins.

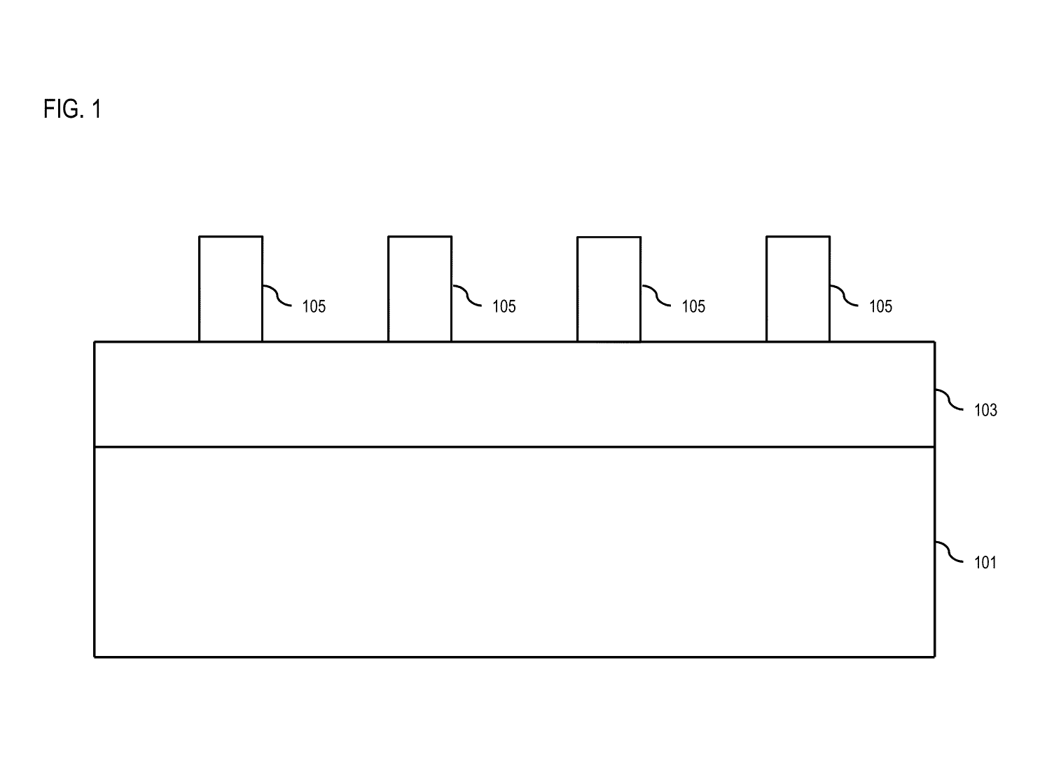

Adverting to FIG. 1, a method for forming a vertical capacitance structure, according to an exemplary embodiment, begins with FIGS. 1 through 7 for forming fins according to a sidewall spacer/image transfer (SIT) approach. However, it is to be understood that the described fins may be formed according to other processes without departing from the spirit and scope of the disclosure. It is also to be understood that the final fin width and distance between the fins depends on the resist or dummy line length and the distance between the dummy lines, as described below. The capacitance of the below-described vertical capacitance structure will be defined by the geometry of the fins, including the height and the count, as well as the thickness and k-factor of the isolation layer.

FIG. 1 illustrates a hardmask 103 formed above a substrate 101, such as bulk silicon (Si). The hardmask 103 can be formed of any suitable hardmask material for the described process, such as silicon nitride (SiN). Further, although described as bulk Si, the substrate 101 can be any suitable semiconductor substrate material. Above the hardmask 103 are patterned resist or dummy lines 105 formed of poly-silicon (poly-Si). The resist or dummy lines 105 correspond to mandrels for forming fins and form the beginning of the SIT process. Prior to the SIT process, well isolation implants may be formed within the substrate 101.

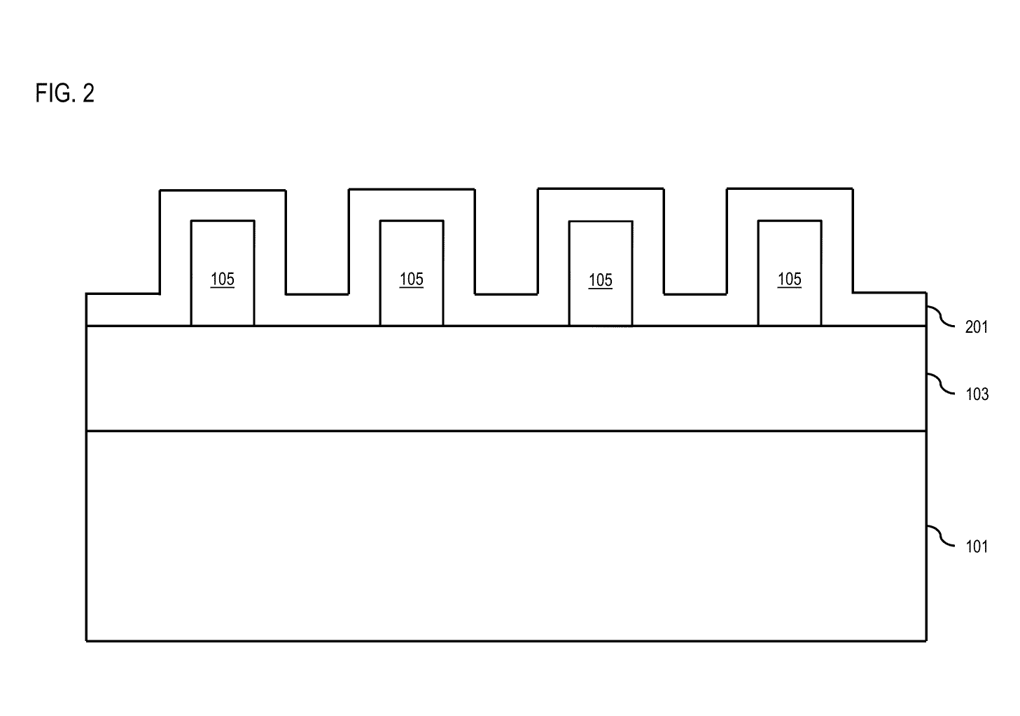

Adverting to FIG. 2, a spacer/sidewall layer 201 is conformally formed over the hardmask 103 and the resist or dummy lines 105. The spacer/sidewall layer 201 is conformally formed to retain the general shape of peaks and valleys defined by the resist or dummy lines 105 above the hardmask 103. The spacer/sidewall layer 201 can be formed of any spacer and/or sidewall material suitable for the described process, and can be formed to a thickness of 20 to 30 nm, such as 25 nm. The thickness of the spacer/sidewall layer 201 will define the final fin width and the length of the resist or dummy lines 105 will define the final distance between the lines.

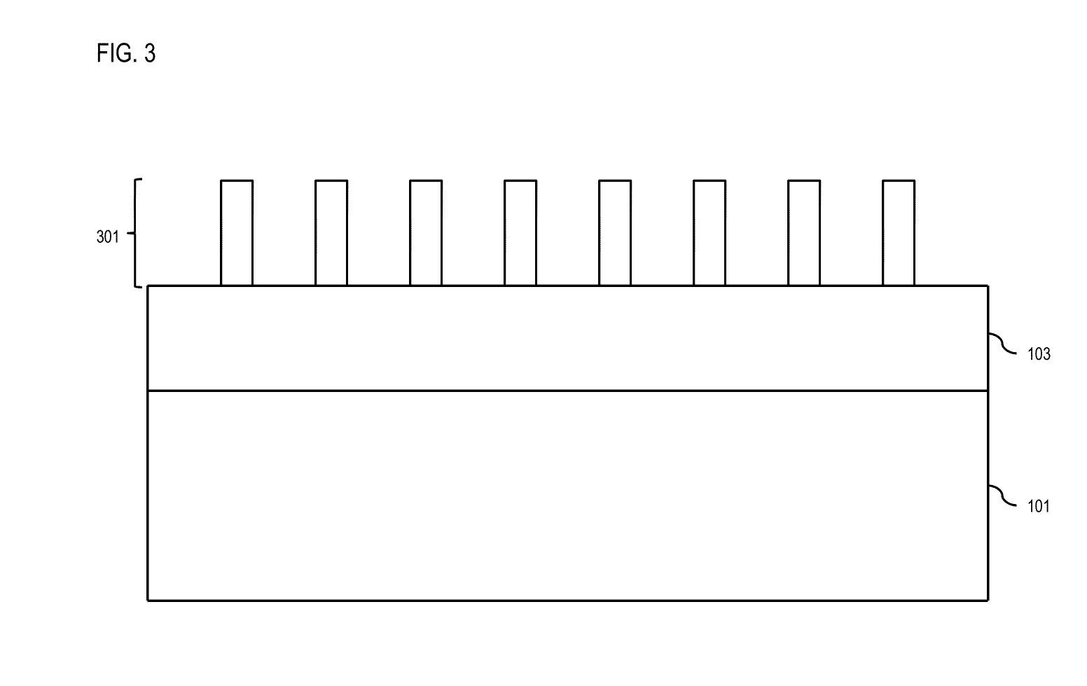

As illustrated in FIG. 3, horizontal portions of the spacer/sidewall layer 201 and the entire resist or dummy lines 105 are removed such that only vertical portions 301 of the spacer/sidewall layer 201 layer remain. The vertical portions 301 represent the portions of the spacer/sidewall layer 201 previously on opposite sides of the resist or dummy lines 105. The subsequently formed fin structure is defined according to the vertical portions 301, as further described below.

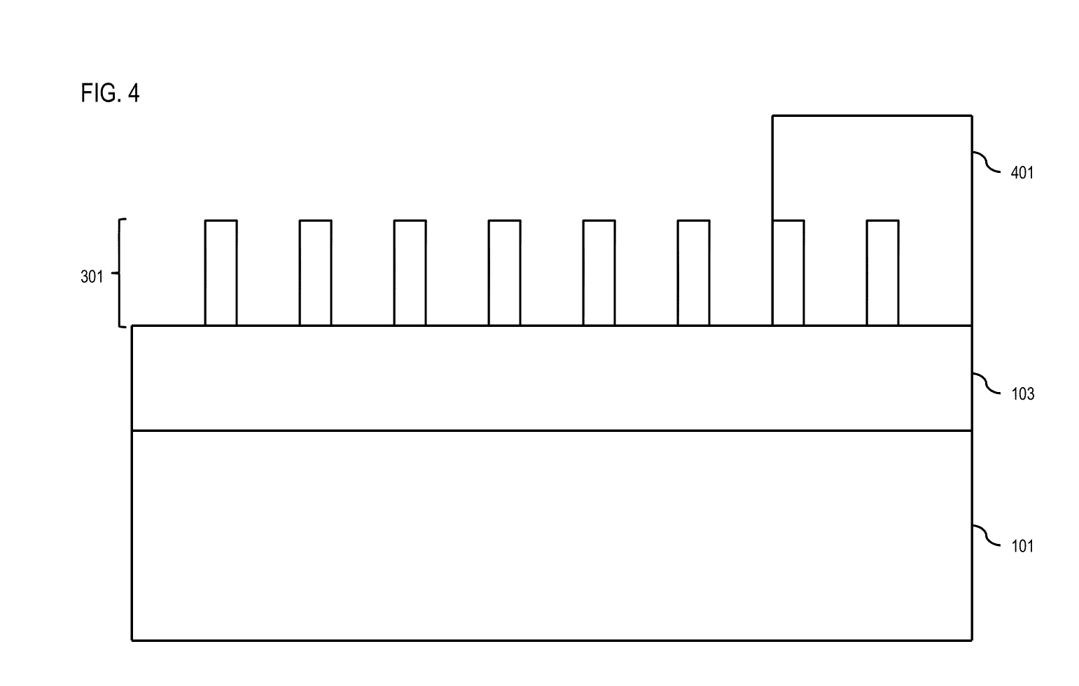

FIG. 4 illustrates a cut/block mask 401 formed over some of the vertical portions 301. The cut/block mask 401 defines areas where fins will not be formed according to the below process. Thus, the cut/block mask 401 can define a non-capacitance area, such as device area, separate from a capacitance area.

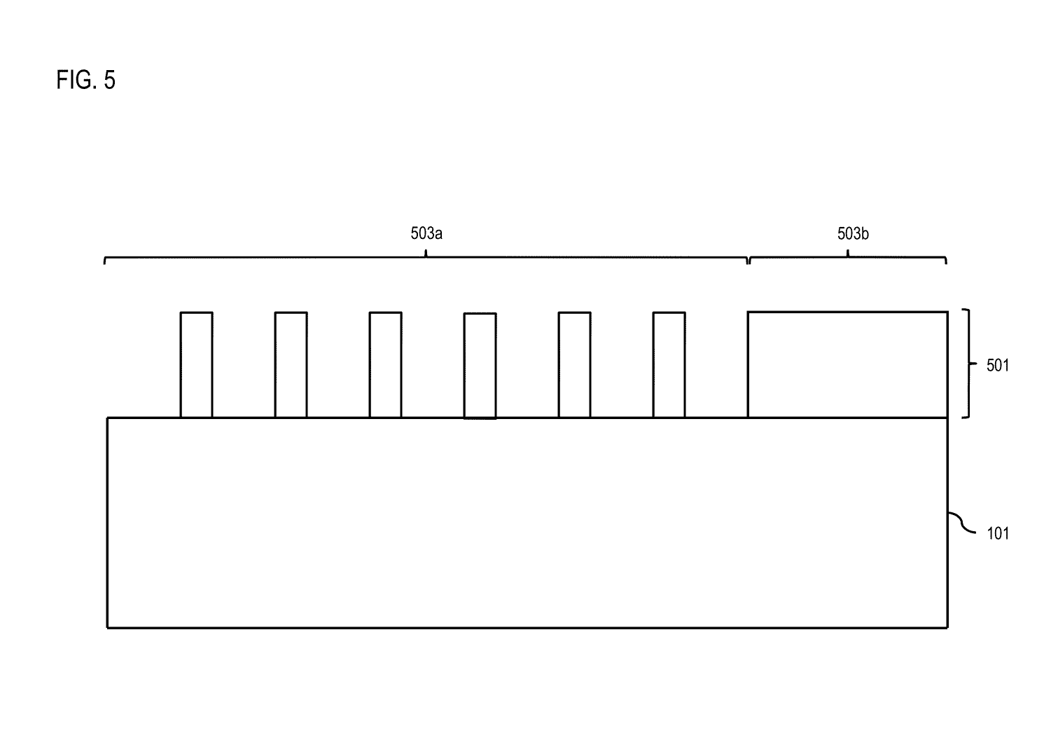

Adverting to FIG. 5, the pattern defined by the vertical portions 301 and the cut/block mask 401 is transferred to the hardmask 103, forming the patterned hardmask 501. The patterned hardmask 501 may be formed according to an etching process, and the vertical portions 301 and the cut/block mask 401 above the patterned hardmask 501 can be removed, such as by chemical mechanical polishing (CMP). Thus, FIG. 5 illustrates the patterned hardmask 501 after creating capacitance area 503a and non-capacitance area 503b.

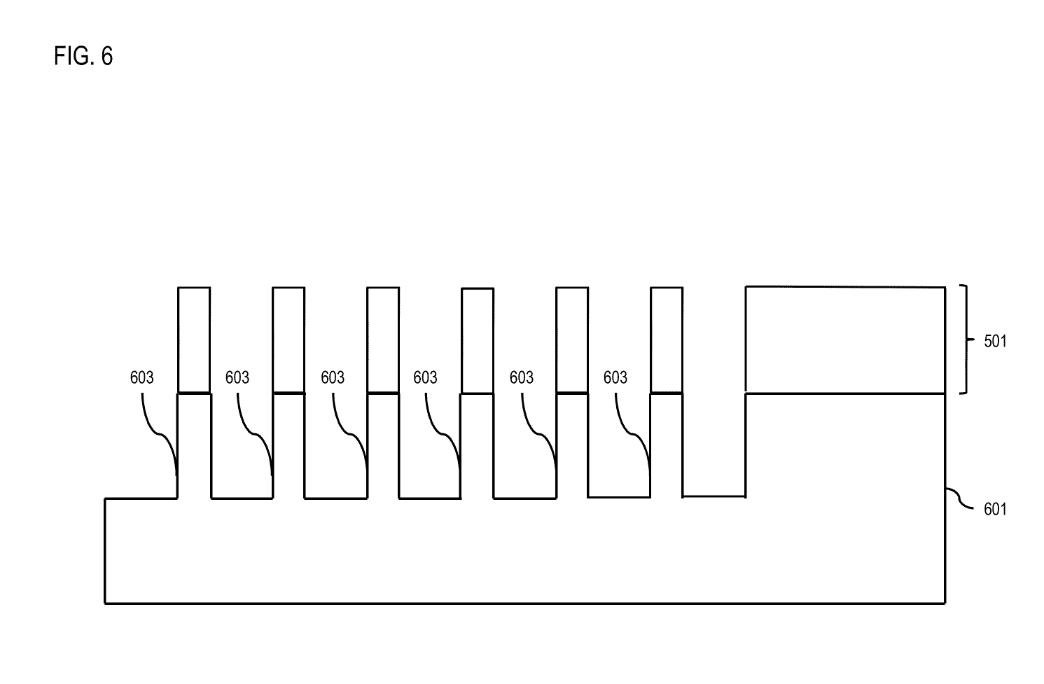

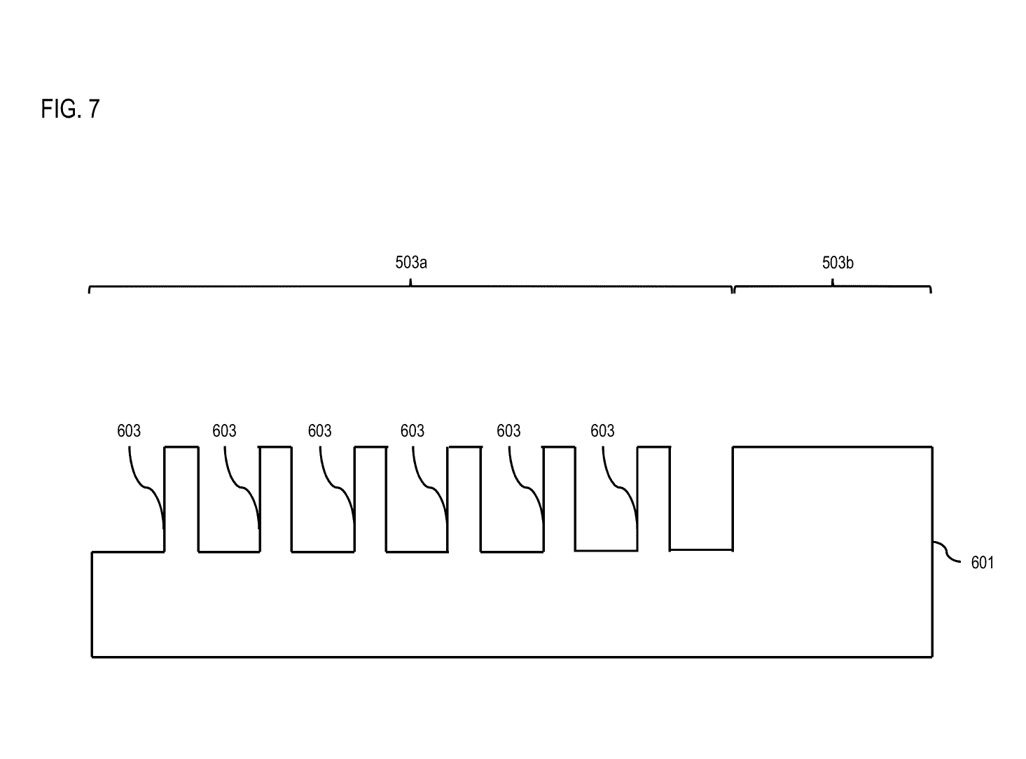

Adverting to FIG. 6, using the patterned hardmask 501, fins 603 are formed by etching into the substrate 101, forming a patterned substrate 601. Subsequently, the patterned hardmask 501 can be removed, such as by a wet etch removal process with phosphoric acid (H₃PO₄), as illustrated in FIG. 7. FIG. 7 further illustrates the patterned substrate 601 with the fins 603 within the capacitance area 503a, and the non-capacitance area 503b. Upon forming the patterned substrate 601 with fins 603, additional ion implantation may occur, such as fin isolation implants or additional well implants. Again, however, it is understood that FIGS. 1 through 7 merely illustrate one exemplary process for forming fins 603 from a substrate 101, and are not meant to be limiting. The fins 603 may be formed according to any suitable processing.

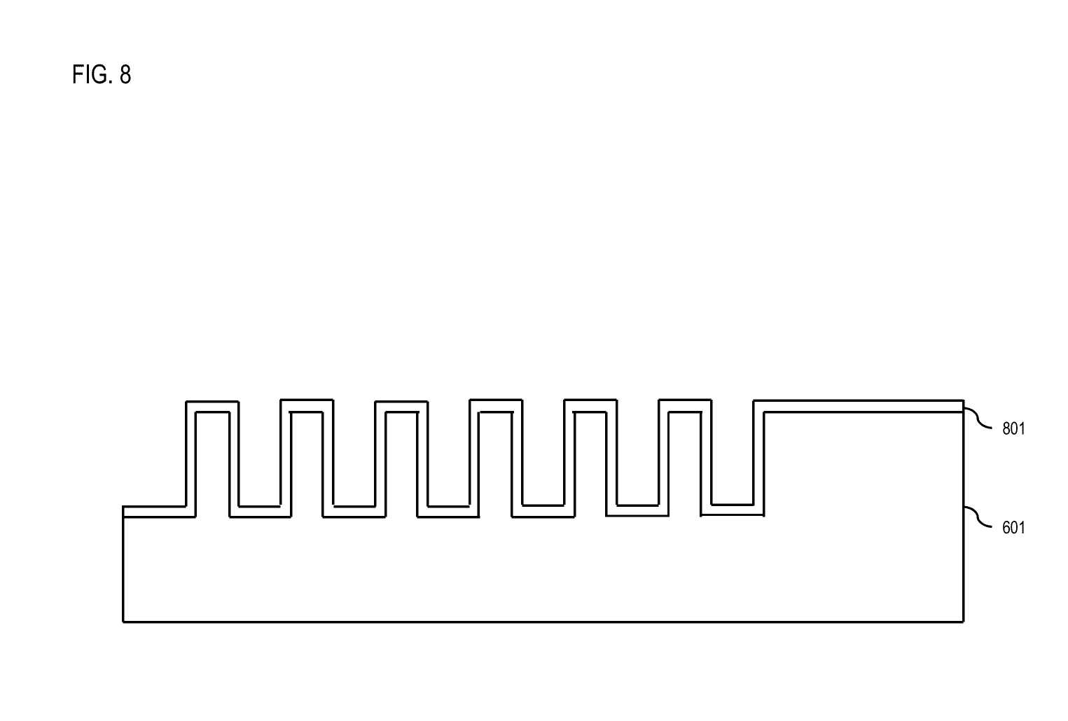

FIGS. 8 through 12 illustrate forming a vertical capacitance structure using the fin structure described in previous FIGS. 1 through 7, in accordance with an exemplary embodiment. Adverting to FIG. 8, a metal layer 801 is conformally formed over the patterned substrate 601, including the fins 603. The metal layer 801 can be a work function metal, such as lanthanum (La), tantalum (Ta), aluminum (Al), titanium nitride (TiN), etc., such as when combined with a replacement metal gate flow, and can be formed to a thickness of 20 to 60 nm, such as 40 nm.

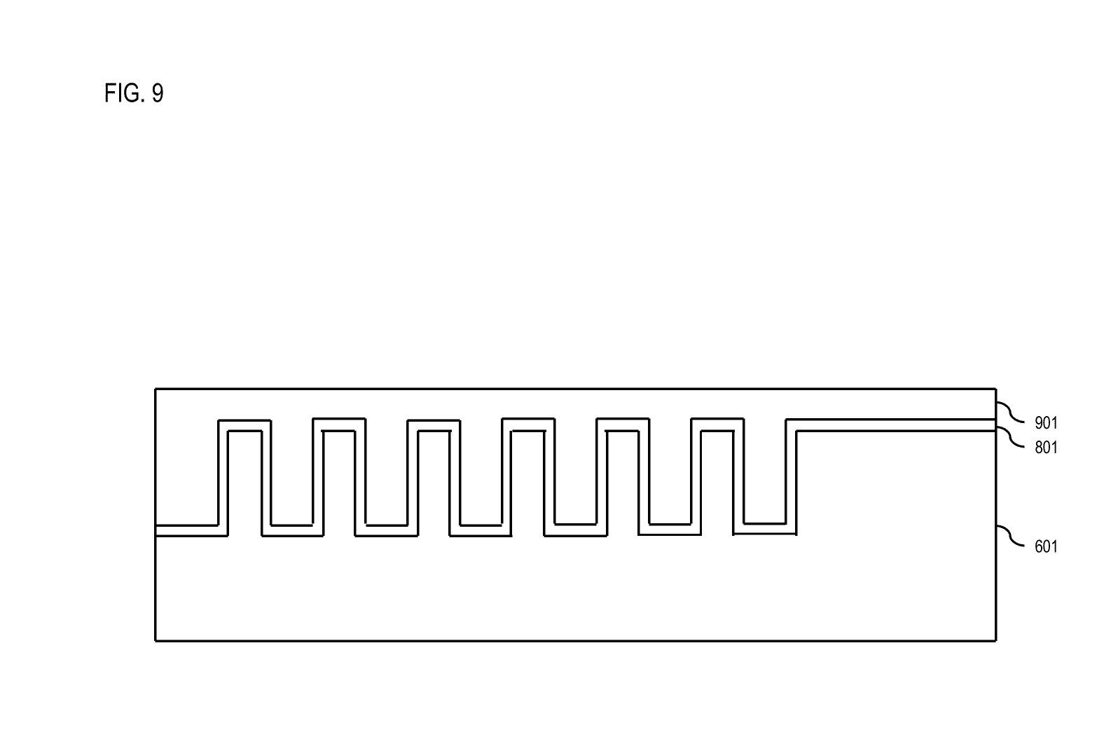

Next, an isolation layer 901 is formed over the metal layer 801, as illustrated in FIG. 9. The isolation layer 901 may be formed of any suitable isolation material, such as silicon oxide (SiO₂), silicon oxynitride (SiON), SiN, etc., and can be formed to a thickness of 20 to 60 nm, such as 40 nm. After forming the isolation layer 901, the isolation layer 901 may be planarized (not shown for illustrative convenience), such as by CMP, to control the conformity of the structure. However, the isolation layer 901 is controlled to have a top surface of the isolation layer 901 remain a threshold height above the top of the fins 603 to control the capacitance of the resulting structure.

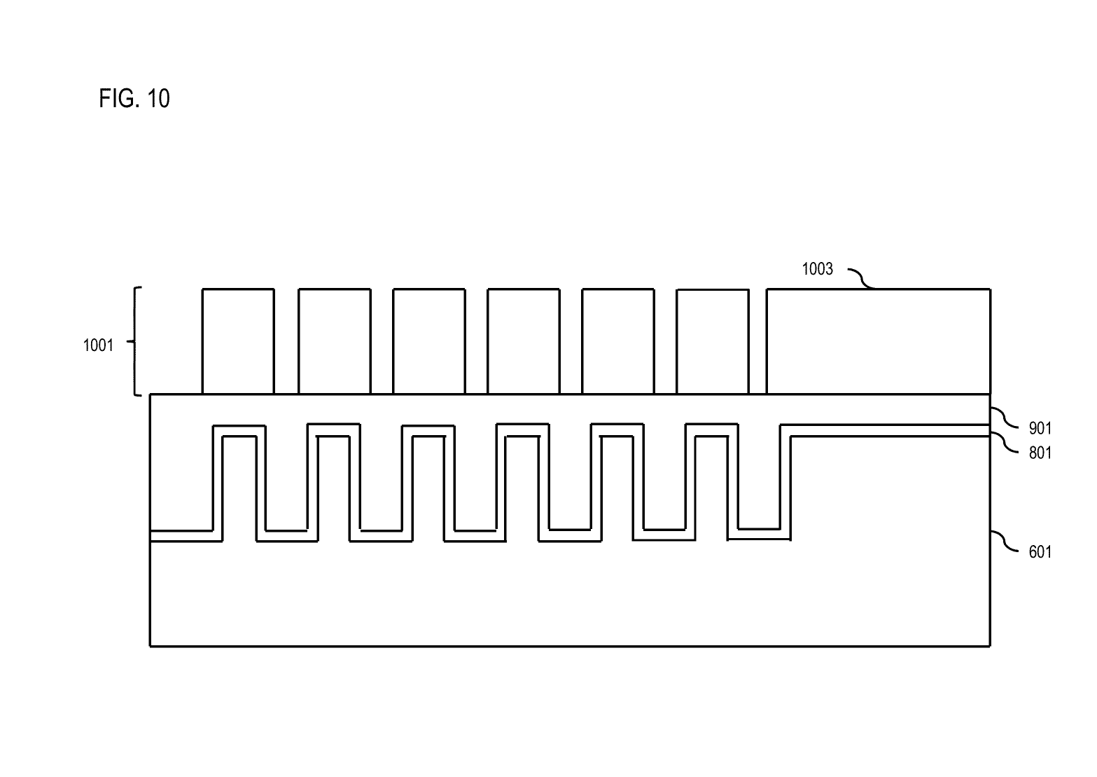

Adverting to FIG. 10, a resist mask 1001, including a cut off area 1003, is formed above the isolation layer 901. The resist mask 1001 can be formed according to an SIT process, such as the process described above. Alternatively, a hardmask may be formed in place of the resist mask 1001. This step creates a mask for forming the trenches for the vertical capacitance structure. The cut off area 1003 defines the non-capacitance area.

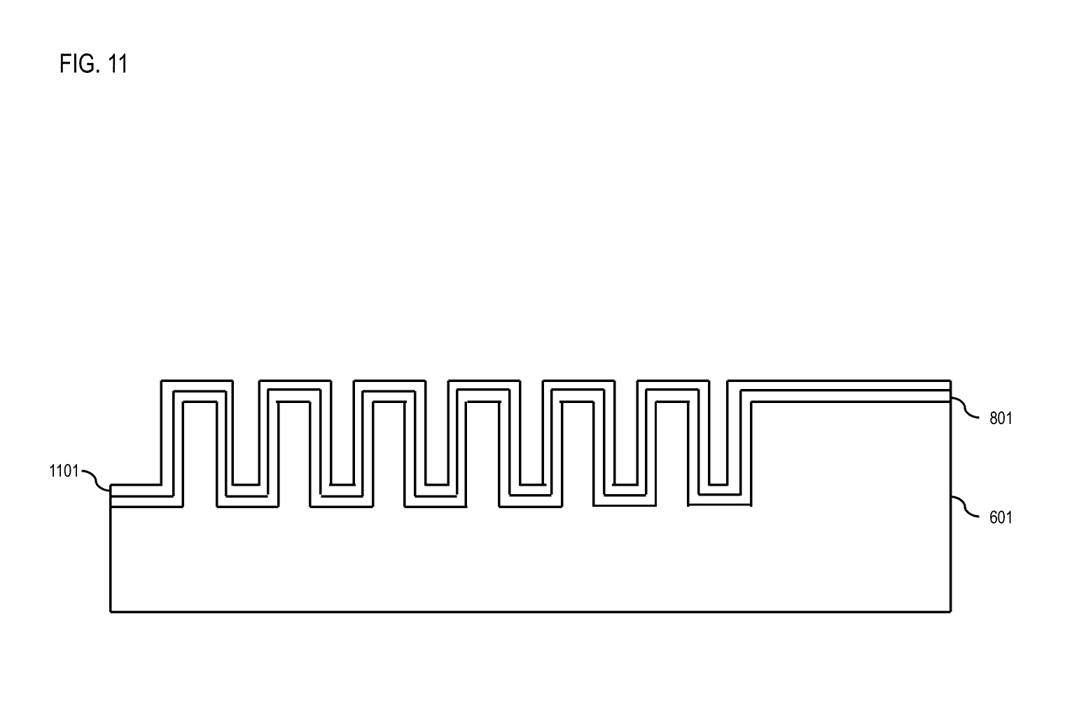

After forming the resist mask 1001, the isolation layer 901 is etched forming trenches between vertical portions of the metal layer 801 formed over the fins 603, as illustrated in FIG. 11. As further illustrated, the resist mask 1001 may be removed according to a suitable processing, such as by CMP. The result of etching the isolation layer 901 forms a conformal isolation layer 1101 over the metal layer 801 on the fins 603.

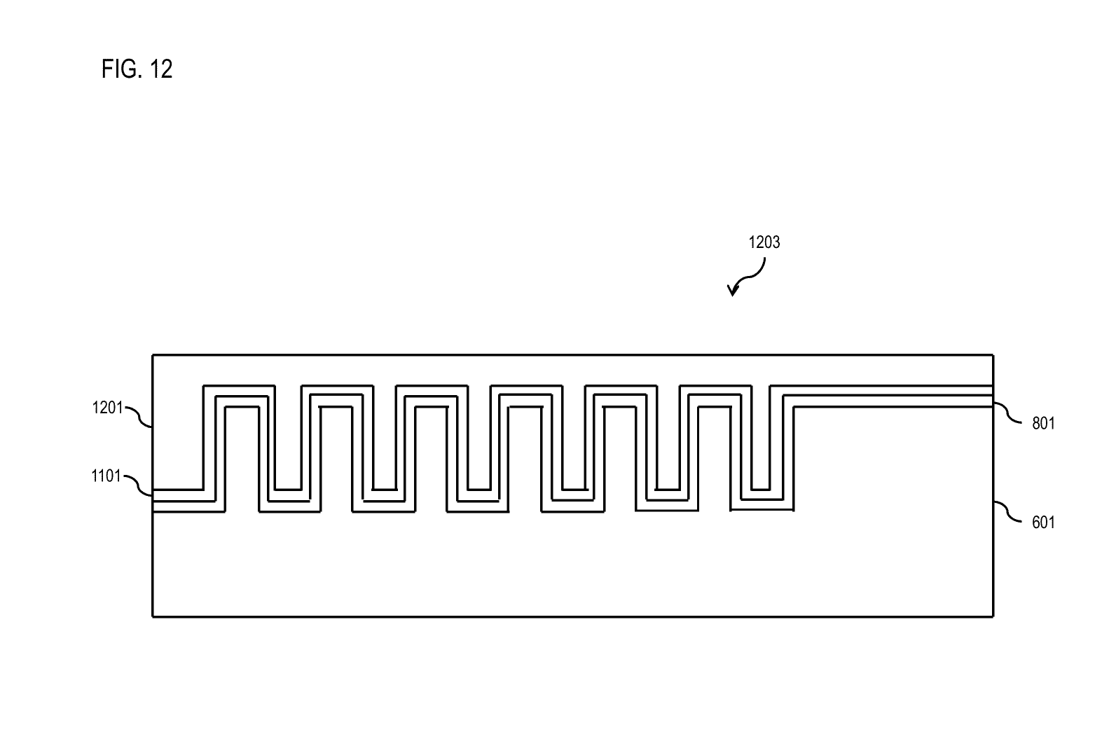

Adverting to FIG. 12, a metal layer 1201 is formed over the conformal isolation layer 1101. The metal layer 1201 can be formed according to any suitable process. Like the metal layer 801, the metal layer 1201 can be a work function metal, such as La, Ta, Al, TiN, etc., such as when combined with a replacement metal gate flow, and can be formed to a thickness of 20 to 60 nm, such as 40 nm. The conformal isolation layer 1101 sandwiched between the metal layer 801 and the metal layer 1201 forms a vertical capacitance structure 1203. As illustrated in FIG. 12, the metal layer 1201 may fill the trenches formed by the conformal isolation layer 1101 and the metal layer 801 on the fins, with the top of the metal layer 1201 being level.

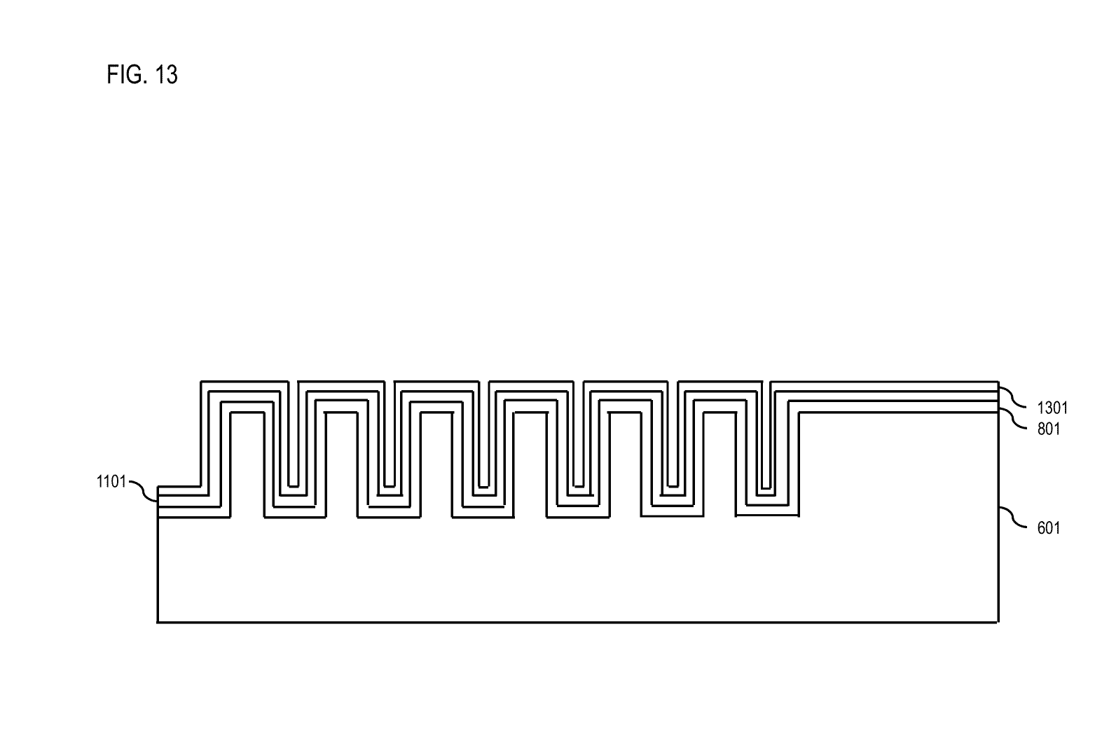

Alternatively, FIG. 13 illustrates a conformal metal layer 1301 formed above the conformal isolation layer 1101, rather than the metal layer 1201. The conformal metal layer 1301 can be formed according to any suitable process that forms a conformal metal layer, such as by atomic layer deposition (ALD), and can be formed to a thickness of 20 to 60 nm, such as 40 nm. The conformal metal layer 1301 can be formed of La, Ta, Al, TiN, etc. The conformal metal layer 1301 acts as an upper electrode for the vertical capacitance structure 1203 and the metal layer 801 acts as a lower electrode for the vertical capacitance structure 1203.

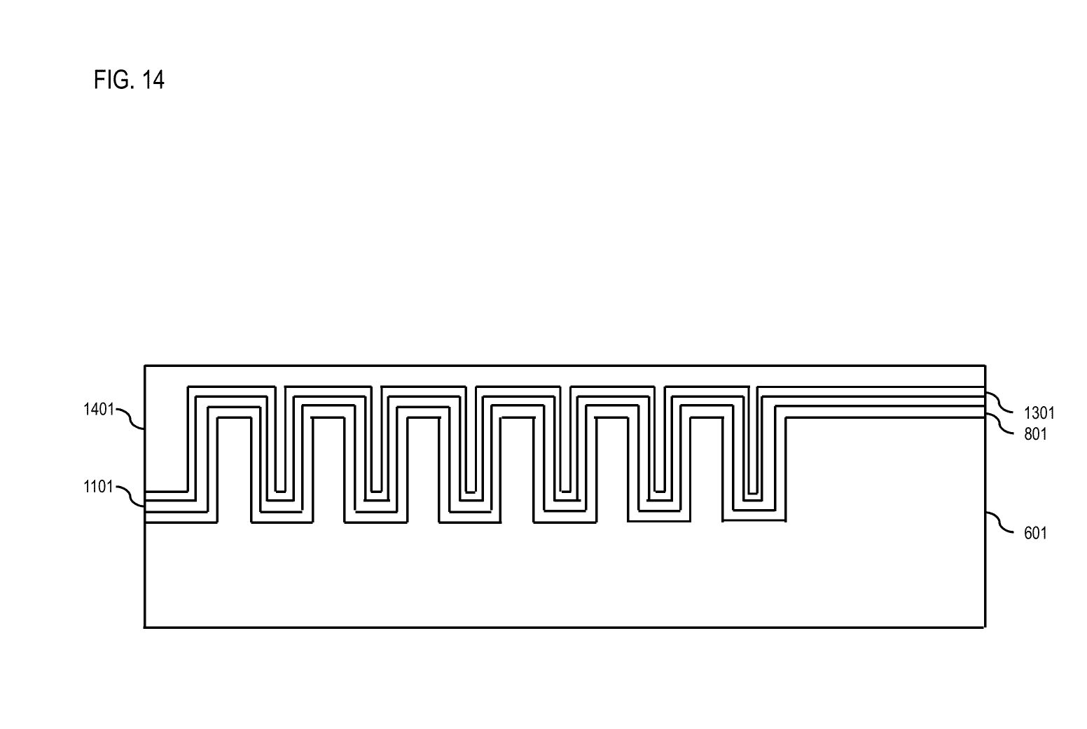

Whether metal layer 1201 or conformal metal layer 1301 is formed may vary depending on the specific capacitance structure desired. If either the conformal metal layer 1301 or the metal layer 1201 is formed, a resist layer 1401 may be formed above the metal layer, as illustrated in FIG. 14 (in the case of a conformal metal layer 1301). The resist layer 1401 may be formed of any suitable resist material.

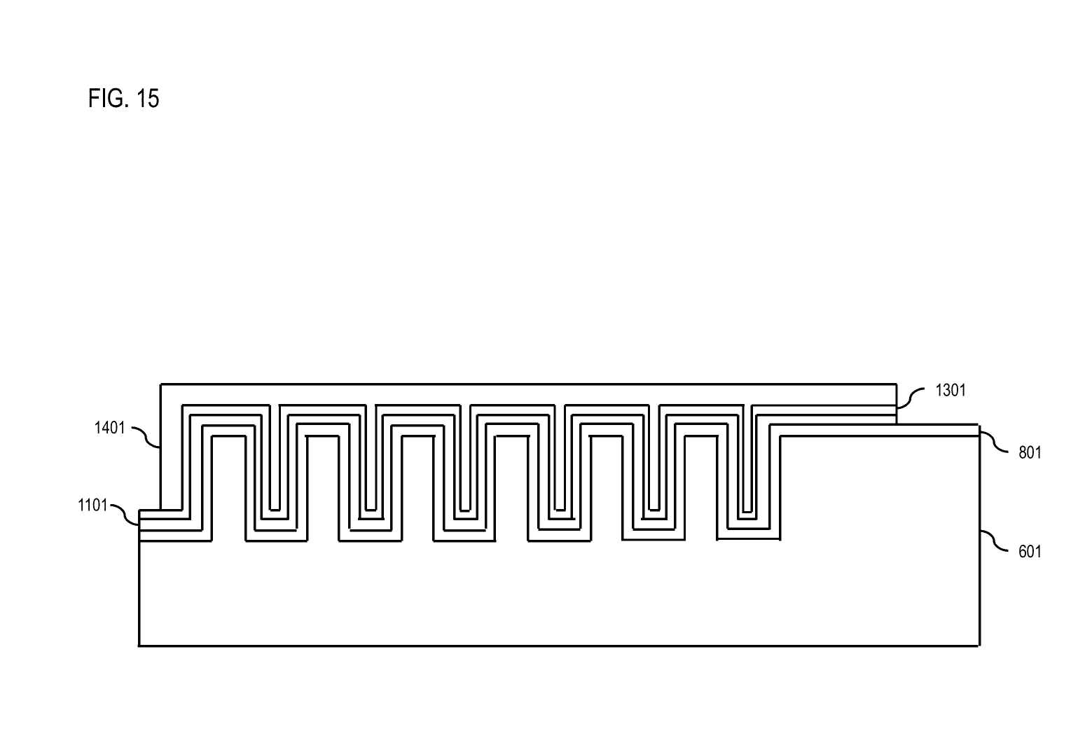

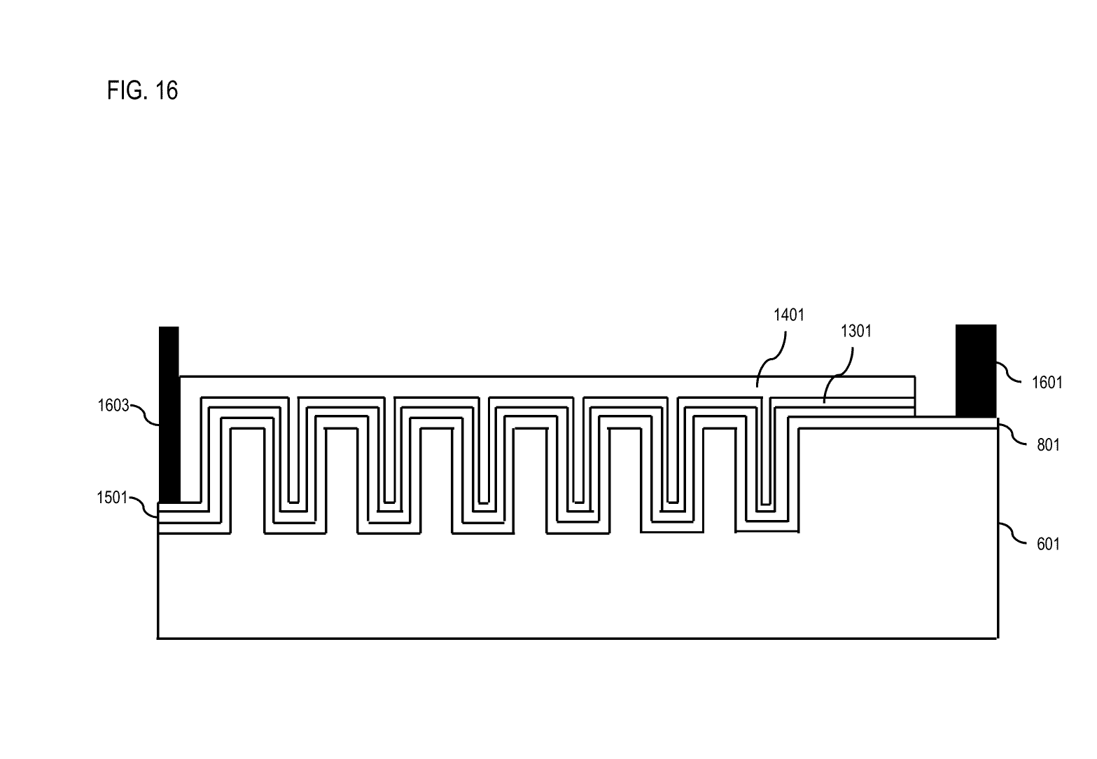

Adverting to FIG. 15, portions of the resist layer 1401, conformal metal layer 1301, and conformal isolation layer 1101 can be removed on one side of the vertical capacitance structure 1203 to expose a portion of the metal layer 801. Similarly, a portion of the resist layer 1401 may be removed on the other side of the vertical capacitance structure 1203 to expose a portion of the conformal metal layer 1301. The portions can be removed according to any suitable processing, such as by etching.

Capacitor contacts 1601 and 1603 contacting the metal layer 801 and the conformal metal layer 1301, respectively, are then formed. The capacitor contacts 1601 and 1603 may be formed of any suitable contact material. Although not shown (for illustrative convenience), additional side wall isolation may be formed surrounding the capacitor contacts 1601 and 1603 to prevent a short between the capacitor contacts 1601 and 1603 and other portions of the vertical capacitance structure 1203.

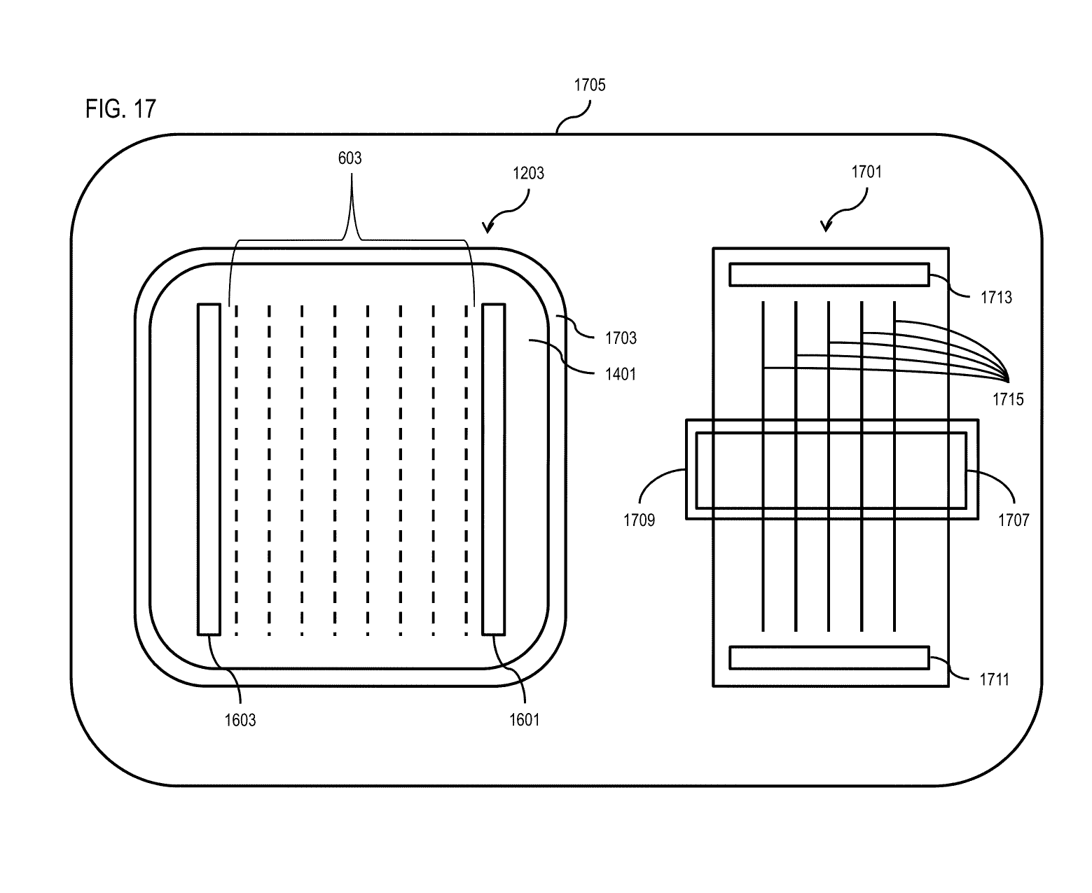

FIG. 17 represents a plan view of the vertical capacitance structure 1203 together with a FinFET 1701. As described above, the vertical capacitance structure 1203 may include fins 603 represented by the dashed, parallel vertical lines, that are below the resist layer 1401, in addition to the other layers explained above that are not shown (for illustrative convenience). The vertical capacitance structure 1203 further includes the capacitor contacts 1601 and 1603. Further, a spacer 1703 can be formed surrounding the vertical capacitance structure 1203 to isolate the structure from other devices on a substrate 1705, such as the FinFET 1701, which includes gate 1707 surrounded by spacer 1709, source contact 1711, drain contact 1713, and fins 1715. Depending on the characteristics of the fins 1715 of the FinFET 1701, the process steps described above for forming the fins 603 of the vertical capacitance structure 1203 can also form the fins 1715 for the FinFET 1701. Thus, the non-capacitance areas described above may not be blocked if such areas will also include fins at the same dimensions as the fins of the vertical capacitance structure 1203.

The embodiments of the present disclosure achieve several technical effects, including permitting several different and new types of capacitance structures within a smaller area than conventional planar capacitance structures, and setting target capacitances by the thickness of the isolation stack materials as well as the trench depth and the number of fins used within a capacitance structure. Further, the present disclosure does not require major changes on the design side because implementation is based on standard FinFET concepts, and there is no effect, such as a need for re-centering, on standard device structures. Additionally, with the vertical capacitance structure in combination with a classical replacement gate FinFET approach, a significant area advantage can be achieved, obtaining an increased capacitance on a lower active area by moving the capacitance into the third dimension. The present disclosure enjoys industrial applicability associated with the designing and manufacturing of any of various types of highly integrated semiconductor devices used in microprocessors, smart phones, mobile phones, cellular handsets, set-top boxes, DVD recorders and players, automotive navigation, printers and peripherals, networking and telecom equipment, gaming systems, and digital cameras, particularly for 14 nm technology nodes and beyond.

In the preceding description, the present disclosure is described with reference to specifically exemplary embodiments thereof. It will, however, be evident that various modifications and changes may be made thereto without departing from the broader spirit and scope of the present disclosure, as set forth in the claims. The specification and drawings are, accordingly, to be regarded as illustrative and not as restrictive. It is understood that the present disclosure is capable of using various other combinations and embodiments and is capable of any changes or modifications within the scope of the inventive concept as expressed herein.

What is claimed is:

1. A method comprising:
forming fins on a substrate;
conformally forming a first metal layer over the fins;
conformally forming an insulation layer over the first metal layer; and
forming a second metal layer over the insulation layer.

2. The method according to claim 1, further comprising:
forming a first contact connected to the first metal layer,
wherein the first contact is isolated from the second metal layer.

3. The method according to claim 1, further comprising:
forming a second contact connected to the second metal layer,
wherein the second contact is isolated from the first metal layer.

4. The method according to claim 1, comprising conformally forming the second metal layer over the insulation layer.

5. The method according to claim 1, further comprising:
forming a resist layer over the second metal layer.

6. The method according to claim 1, wherein conformally forming the insulation layer comprises:
blanket depositing insulation material over the first metal layer;
forming a patterned hardmask over the insulation material, wherein portions of the insulation material exposed by the patterned hardmask are aligned with trenches in the substrate between the fins;
etching the insulation material according to the patterned hardmask; and
removing the patterned hardmask and a top portion of the insulation material.

7. The method according to claim 1, comprising:
forming the first metal layer to a thickness of 20 to 60 nm; and
forming the second metal layer to a thickness of 20 to 60 nm.

8. The method according to claim 1, comprising forming the fins to a height of 80 to 200 nm and a pitch of 180 to 400 nm.

9. The method according to claim 1, comprising forming 50 to 2000 of the fins.

10. A device comprising:
a substrate;
fins formed on the substrate;
a conformal first metal layer over the fins;
a conformal insulation layer over the first metal layer; and
a second metal layer over the insulation layer.

11. The device according to claim 10, further comprising:
a first contact connected to the first metal layer,
wherein the first contact is isolated from the second metal layer.

12. The device according to claim 10, further comprising:
a second contact connected to the second metal layer,
wherein the second contact is isolated from the first metal layer.

13. The device according to claim 10, wherein the second metal layer is conformal.

14. The device according to claim 10, further comprising:
a resist layer over the second metal layer.

15. The device according to claim 1, wherein the first metal layer is formed to a thickness of 20 to 60 nm, and the second metal layer is formed to a thickness of 20 to 60 nm.

16. The device according to claim 1, wherein the fins are formed to a height of 80 to 200 nm and a pitch of 180 to 400 nm.

17. The device according to claim 1, comprising 50 to 2000 of the fins.

18. A method comprising:
defining a fin area and a device area on a substrate, the fin area including 50 to 2000 fins;
conformally forming a first metal layer over the fin area to a thickness of 20 to 60 nm;
conformally forming an insulation layer over the first metal layer;
forming a second metal layer over the insulation layer to a thickness of 20 to 60 nm; and
forming a resist layer over the second metal layer.

19. The method according to claim 18, further comprising:
forming a first contact to the first metal layer; and
forming a second contact to the second metal layer,
wherein the first contact is isolated from the second metal layer, and the second contact is isolated from the first metal layer.

20. The method according to claim 18, further comprising:
forming a FinFET device on the device area.
